(19) United States
(12) Patent Application Publication
(10) Pub. No.: US 2009/0065806 A1
(43) Pub. Date: Mar. 12, 2009

(54) MOS TRANSISTOR AND FABRICATION METHOD THEREOF

(76) Inventor: Dae-Young Kim, Gangnam-gu (KR)

Correspondence Address: SHERR & VAUGHN, PLLC, 620 HERNDON PARKWAY, SUITE 200, HERNDON, VA, 20170, US

(21) Appl. No.: 12/197,268

(22) Filed: Aug. 24, 2008

(30) Foreign Application Priority Data
Sep. 7, 2007 (KR) 10-2007-0090850

(51) Int. Cl. H01L 27/092; H01L 21/8238

(52) U.S. Cl. 257/190; 438/221; 257/E27.062; 257/E21.632

(57) ABSTRACT

A MOS transistor and a fabrication method thereof are disclosed. The mobility of electrons or holes serving as charge carriers of the MOS transistor can be improved by forming a lattice stress-causing material in source/drain regions of a MOS transistor or by forming a gapping layer having a tensile stress in the MOS transistor. As a result, a driving current of the MOS transistor may be reduced.

The present application claims priority under 35 U.S.C. 119 to Korean Patent Application No. 10-2007-0090850 (filed on Sep. 7, 2007), which is hereby incorporated by reference in its entirety.

### BACKGROUND

In recent years, with the development of information communication technology, the need for a highly integrated DRAM (Dynamic Random Access Memory) has been increasing. Accordingly, there is a need to improve the characteristics of a metal-oxide semiconductor field effect transistor (MOSFET) used in a periphery region of a high performance DRAM. However, due to technical limitations caused by the characteristics and structure of a cell array transistor, the DRAM process has characteristic degradation factors, such as the non-application of a silicide process, a thin gate spacer, and a high thermal budget. Moreover, additional gate oxide scaling to improve the speed of 50 nm DRAMs will lead to increased gate leakage current and therefore increased current consumption.

### SUMMARY

Embodiments relate to a MOS transistor and, more particularly, to a MOS transistor, which improves the mobility of electrons or holes serving as carriers of the MOS transistor and a fabrication method thereof. Embodiments relate to improving the mobility of electrons or holes serving as carriers by forming a lattice stress-causing material in source/drain regions of a MOS transistor and forming a gapping layer having a tensile stress upon thermal treatment in the MOS transistor.

Embodiments relate to a fabrication method of a MOS transistor which includes: forming a device isolation film for isolating a first type MOS transistor region and a second type MOS transistor region over a semiconductor substrate; forming gate electrodes over the first type MOS transistor region and second type MOS transistor region, respectively; forming lightly doped drain regions over the first type MOS transistor region and second type MOS transistor region, respectively; forming source/drain regions over the first type MOS transistor region and second type MOS transistor region, respectively; forming a protective film over the first type MOS transistor region; selectively forming a lattice stress-causing material over the source/drain regions of the second type MOS transistor region; and removing the protective film.

Embodiments relate to a MOS transistor which includes: a first type MOS transistor region in which source/drain regions, lightly doped drain regions, and gate electrodes are formed over a semiconductor substrate. A second type MOS transistor region is included in which source/drain regions having a lattice stress-causing material, lightly doped drain regions, and gate electrodes are formed over a semiconductor substrate. A device isolation film is included for isolating the first type MOS transistor region and the second type MOS transistor region.

Embodiments relate to a fabrication method of a MOS transistor which includes: forming a device isolation film for isolating a first type MOS transistor region and a second type MOS transistor region over a semiconductor substrate; forming gate electrodes over the first type MOS transistor region and second type MOS transistor region, respectively; forming lightly doped drain regions over the first type MOS transistor region and second type MOS transistor region, respectively; forming source/drain regions over the first type MOS transistor region and second type MOS transistor region, respectively; forming a gapping layer having a tensile stress in the first type MOS transistor region.

Embodiments relate to a MOS transistor which includes: a first type MOS transistor region in which source/drain regions, lightly doped drain regions, and gate electrodes are formed over a semiconductor substrate. A second type MOS transistor region is included in which source/drain regions, lightly doped drain regions, and gate electrodes are formed over a semiconductor substrate. A device isolation film is included for isolating the first type MOS transistor region and the second type MOS transistor region. A gapping layer having a tensile stress is included in the first type MOS transistor region.

Embodiments relate to a fabrication method of a MOS transistor which includes: forming a device isolation film for isolating a first type MOS transistor region and a second type MOS transistor region over a semiconductor substrate; forming gate electrodes over the first type MOS transistor region and second type MOS transistor region, respectively; forming lightly doped drain regions over the first type MOS transistor region and second type MOS transistor region, respectively; forming source/drain regions over the first type MOS transistor region and second type MOS transistor region, respectively; forming a protective film over the first type MOS transistor region; selectively forming a lattice stress-causing material in the source/drain regions of the second type MOS transistor region; and removing the protective film;

Embodiments relate to a MOS transistor which includes a first type MOS transistor region in which source/drain regions, lightly doped drain regions, and gate electrodes are formed over a semiconductor substrate. A second type MOS transistor region is included in which source/drain regions having a lattice stress-causing material, lightly doped drain regions, and gate electrodes are formed over a semiconductor substrate. A device isolation film is included for isolating the first type MOS transistor region and the second type MOS transistor region. A gapping layer having a tensile stress is included in the first type MOS transistor region.

### DRAWINGS

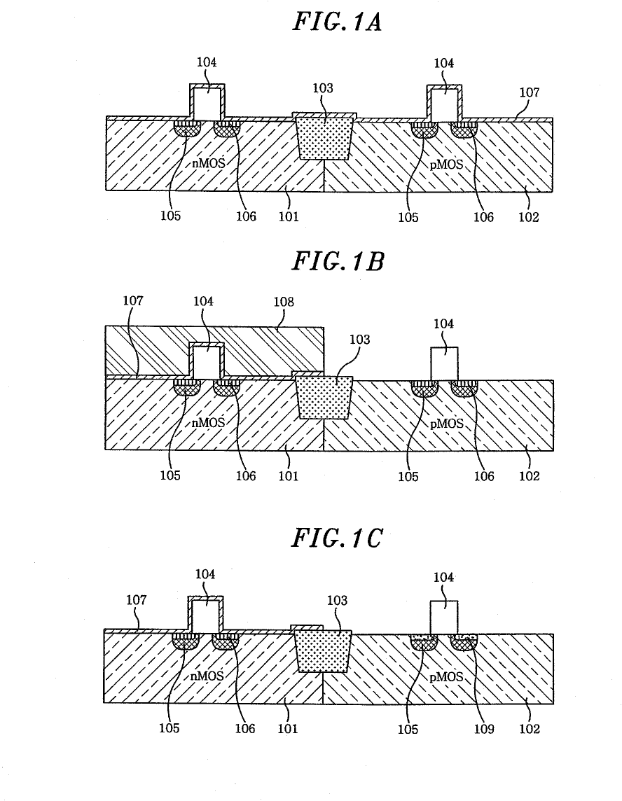

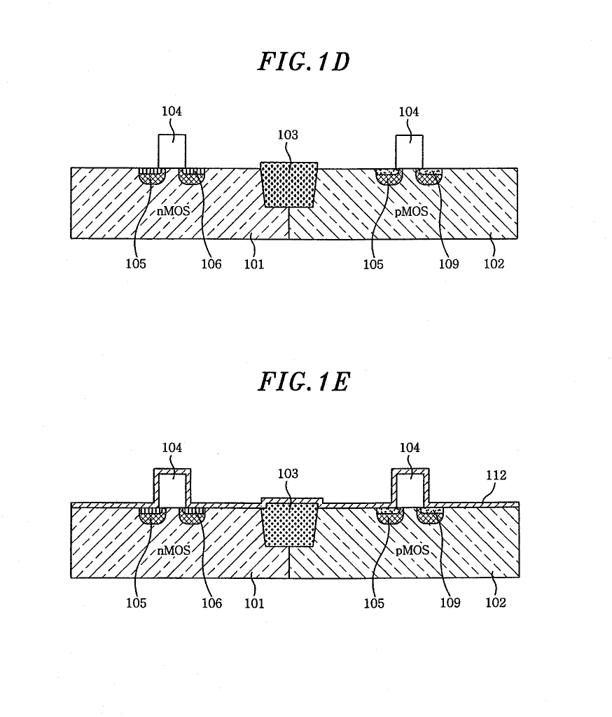

Example FIGS. 1A to 1E are process sequence diagrams for a fabrication method of a MOS transistor in accordance with embodiments.

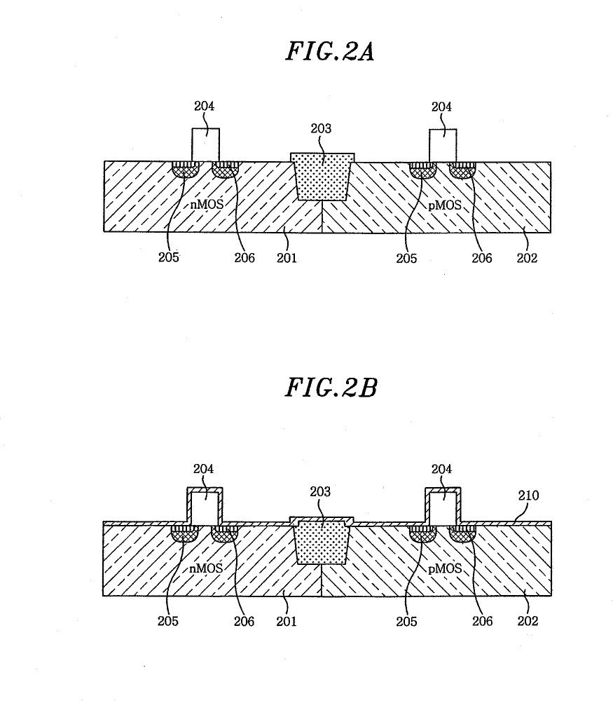

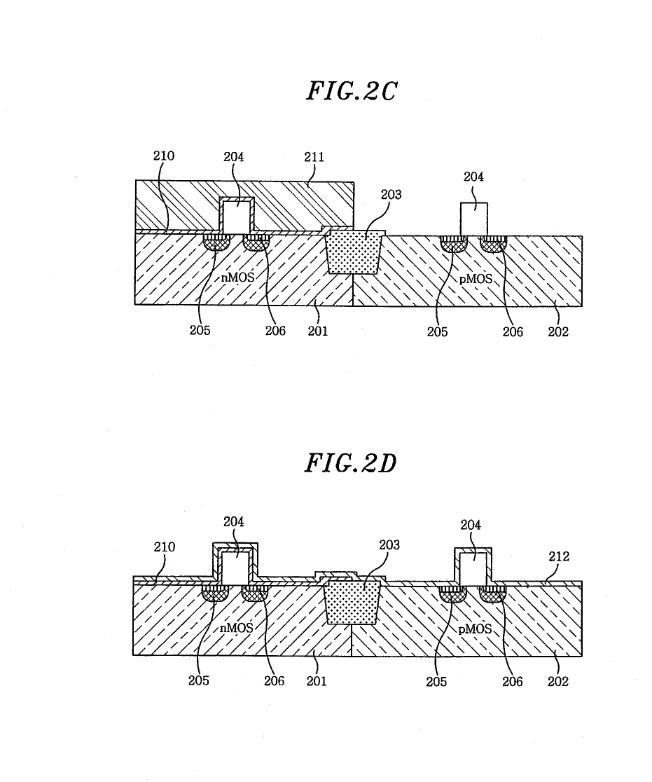

Example FIGS. 2A to 2D are process sequence diagrams for a fabrication method of a MOS transistor in accordance with embodiments.

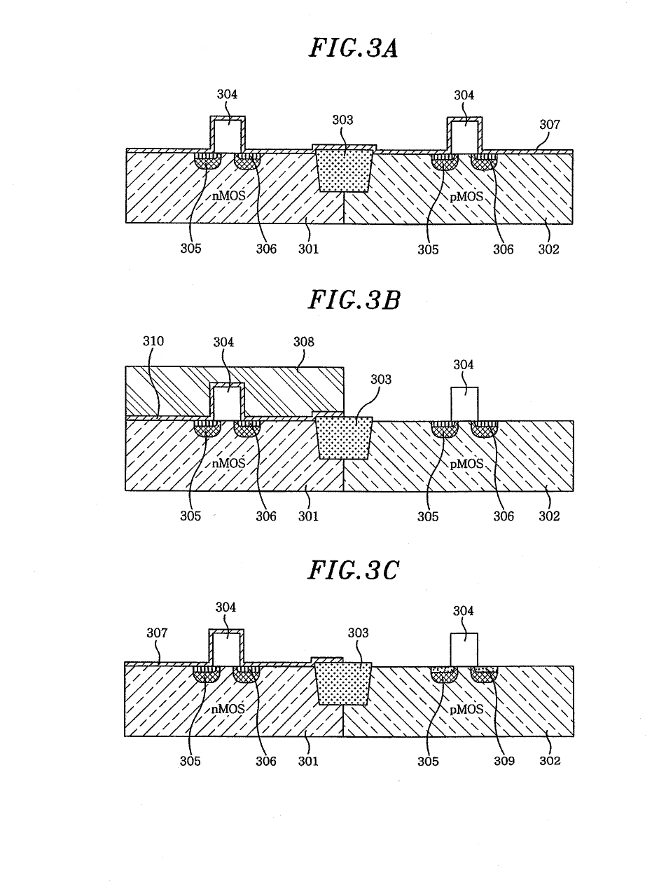

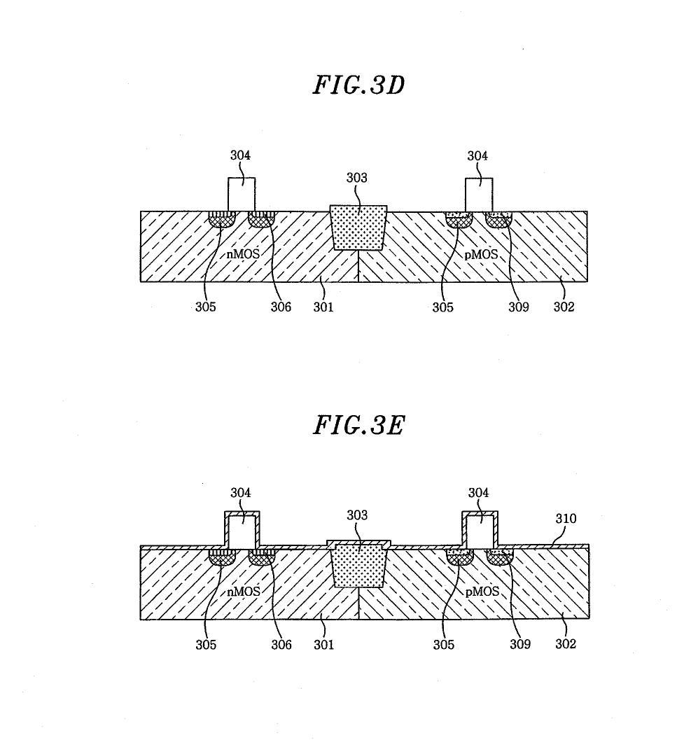

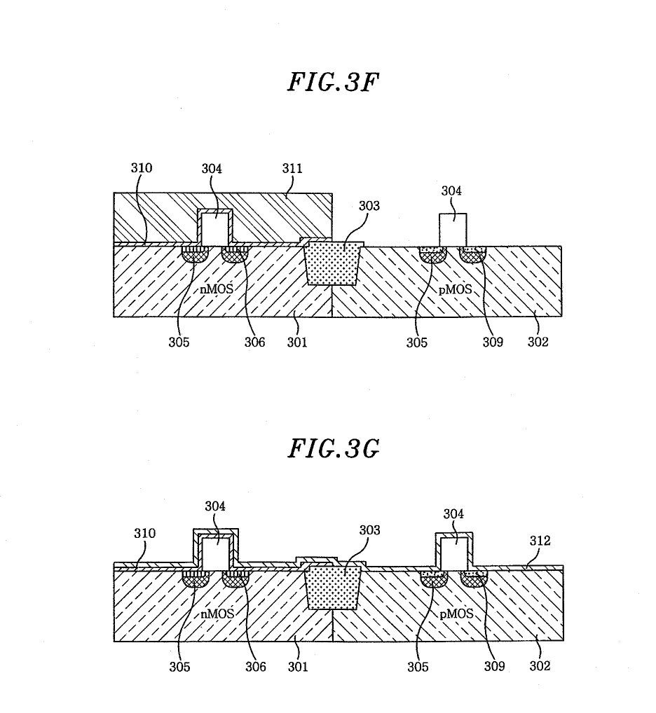

Example FIGS. 3A to 3G are process sequence diagrams for a fabrication method of a MOS transistor in accordance with embodiments.

### DESCRIPTION

Example FIGS. 1A to 1E are process sequence diagrams for a fabrication method of a MOS transistor in accordance with embodiments. Referring to example FIG. 1E, a MOS transistor fabricated in accordance with embodiments may include a first type MOS transistor region with a p type silicon substrate 101 in which source/drain regions 106, LDD regions 105, and gate electrodes 104 may be formed over a semiconductor substrate. A second type MOS transistor region in an n-well 102 may have source/drain regions 109 having a lattice stress-causing material, LDD regions 105, and gate electrodes 104 formed over the semiconductor substrate. A device isolation film 103 may be included for isolating the first type MOS transistor region and the second type MOS transistor region.

A fabrication process of such a MOS transistor will be described below. Referring to example FIG. 1A, an n-well 102 may be formed over a p type silicon substrate 101 to serve as a semiconductor substrate. A PMOS transistor is formed in the n-well. A device isolation film 103 for isolating active regions of NMOS and PMOS transistors may be formed by an STI (Shallow Trench Isolation) process on the substrates 101 and 102.

A silicon oxide film SiO₂ may be deposited as gate insulating film over the entire surfaces of the substrates 101 and 102. Undoped polysilicon may be deposited thereon, and patterned by a photoexposure and etching process using NMOS and PMOS gate masks, thereby forming gate electrodes 104 in an NMOS region and a PMOS region, respectively. Thereafter, the gate insulating film under each of the gate electrodes 104 may be patterned.

An LDD (Light Doped Drain) ion implantation process using n− and p− dopants, respectively, may be performed on the substrates 101 and 102 of the NMOS region and PMOS region, thereby forming n− and p− LDD regions 105 under the sides of the gate electrodes 104. Then, a source/drain ion implantation process using n+ and p+ dopants, respectively, may be performed on the substrates of the NMOS region and PMOS region, thereby forming n+ and p+ source/drain regions 106 under the sides of the gate electrodes 104. A spacer oxide film 107 may be formed as a protective film over the entire surface of the structure in which the n+ and p+ source/drain regions 106 are formed.

Referring to example FIG. 1B, a photoresist film 108 may be formed over the entire surface of the structure in which the spacer oxide film 107 is formed. The photoresist film 108 over the PMOS region may be selectively removed, leaving the photoresist film over only the NMOS region. The spacer oxide film 107 over the PMOS region may be removed using a PEP (Photo Etching Process).

Referring to example FIG. 1C, the photoresist film 108 may be removed by performing, for example, an ashing process, on the structure in which the spacer oxide film 107 of the PMOS region is removed. Silicon germanium Si,ₓGe₁₋ₓ, serving as a lattice stress-causing material is selectively deposited only in the source/drain regions 106 of the PMOS region. Silicon germanium is not deposited in the source/drain regions 106 of the NMOS region due to the protective film function of the spacer oxide film 107, but only in the source/drain regions 106 of the PMOS region. In the drawings, reference numeral 106 is assigned to the source/drain regions over which no silicon germanium is deposited, and reference numeral 109 is assigned to the source/drain regions over which silicon germanium is deposited. The mobility of electrons or holes serving as charge carriers in the MOS transistor is higher in silicon germanium than in silicon, and hence the mobility of the PMOS region having the source/drain regions 109 over which silicon germanium is deposited is improved.

Referring to example FIG. 1D, the spacer oxide film 107 of the NMOS region may be removed by etching. For instance, the spacer oxide film 107 may be removed by wet etching using a BOE (Buffered Oxide Etch) solution or a dilute HF solution.

Referring to example FIG. 1E, a spacer oxide film 112 to be utilized as an etching stopping film in a subsequent process may be formed over the entire surface of the structure in which the spacer oxide film 107 of the NMOS region is removed. A series of processes including forming an interlayer insulating film, a planarization process, a contact electrode formation process, and a wiring formation process are carried out, thereby completing the semiconductor device.

Example FIGS. 2A to 2D are process sequence diagrams for a fabrication method of a MOS transistor in accordance with embodiments. Referring to example FIG. 2D, the MOS transistor fabricated in accordance with embodiments may include a first type MOS transistor region with a p type silicon substrate 201 in which source/drain regions 206, LDD regions 205, and gate electrodes 204 are formed over a semiconductor substrate. A second type MOS transistor region in an n-well 202 in which source/drain regions 209, LDD regions 205, and gate electrodes 204 are formed over a semiconductor substrate. A device isolation film 203 may be included for isolating the first type MOS transistor region and the second type MOS transistor region. A gapping layer 210 may be formed in the first type MOS transistor region. A thermal treatment creates a tensile stress in the gapping layer.

A fabrication process of such a MOS transistor will be described below. Referring to example FIG. 2A, an n-well 202 may be formed over a p type silicon substrate 201 to serve as a semiconductor substrate. A PMOS transistor is formed in the n-well. A device isolation film 203 for isolating active regions of NMOS and PMOS transistors may be formed by an STI (Shallow Trench Isolation) process on the substrates 201 and 202.

A silicon oxide film SiO2 may be deposited as gate insulating film over the entire surfaces of the substrates 201 and 202. Undoped polysilicon may be deposited thereon, and patterned by a photoexposure and etching process using NMOS and PMOS gate masks, thereby forming gate electrodes 204 in an NMOS region and a PMOS region, respectively. Thereafter, the gate insulating film under each of the gate electrodes 204 may be patterned.

An LDD (Light Doped Drain) ion implantation process using n− and p− dopants, respectively, may be performed on the substrates 201 and 202 of the NMOS region and PMOS region, thereby forming n− and p− LDD regions 205 under the sides of the gate electrodes 204. Then, a source/drain ion implantation process using n+ and p+ dopants, respectively, may be performed on the substrates of the NMOS region and PMOS region, thereby forming n+ and p+ source/drain regions 206 under the sides of the gate electrodes 204.

Referring to example FIG. 2B, a silicon nitride film 210, used as a gapping layer having a tensile stress upon thermal treatment, may be formed over the entire surface of the structure in which the source/drain regions 206 are formed. For example, the silicon nitride film 210 may be deposited using a low pressure chemical vapor deposition (LPCVD) process.

Referring to example FIG. 2C, a photoresist film 211 may be formed over the entire surface of the structure in which the silicon nitride film 210 is formed. The PMOS region is exposed by leaving the photoresist film 211 only in the NMOS region through, for example, a PEP (Photo Etching Process). The silicon nitride film 210 of the PMOS region may be removed by performing wet etching or plasma dry etching using, for example, a phosphoric acid solution, on the structure in which the PMOS region is opened.

The silicon nitride film 210 remains only in the NMOS region. Since the silicon nitride film 210, which has a tensile stress, remains in the NMOS region, a compressive stress develops in response to the tensile stress of the silicon nitride film 210. Since the compressive stress is applied to the gate electrodes 204, a tensile stress as a reactive force against the compressive stress develops in the underside of the gate electrodes 204, i.e., in the substrate 201 of the NMOS region. As the underside of the gate electrodes 204, i.e., the substrate 201 of a channel region, receives a tensile stress, the channel region can obtain the effect of relaxation. When the physical structure of the substrate 201 is relaxed upon receipt of a tensile stress within a limited region, this improves the free movement of electrons or holes. That is, as a tensile stress is applied to the substrate 201 of the NMOS region, the mobility of electrons or holes is improved.

Referring to example FIG. 2D, the photoresist film 211 may be removed by performing, for example, an ashing process, on the structure in which the silicon nitride film 210 of the PMOS region is removed. A spacer oxide film 212 to be utilized as an etch stopping film in a subsequent process may be formed over the entire surface of the structure. A series of processes including forming an interlayer insulating film, a planarization process, a contact electrode formation process, and a wiring formation process are carried out, thereby completing the semiconductor device.

Example FIGS. 3A to 3G are process sequence diagrams for a fabrication method of a MOS transistor in accordance with embodiments. Referring to example FIG. 3G, the MOS transistor fabricated in accordance with embodiments may include a first type MOS transistor region with a p type silicon substrate 301 in which source/drain regions 306, LDD regions 305, and gate electrodes 304 are formed over a semiconductor substrate. A second type MOS transistor region in an n-well 302 may have source/drain regions 309 with a lattice stress-causing material, LDD regions 305, and gate electrodes 304 formed over a semiconductor substrate. A device isolation film 303 may be included for isolating type MOS transistor region and the second type MOS transistor region. A gapping layer 310 which develops a tensile stress upon a thermal treatment may be formed in the first type MOS transistor region.

A fabrication process of such a MOS transistor will be described below. Referring to example FIG. 3A, an n-well 302 may be formed over a p type silicon substrate 301 to serve as a semiconductor substrate. A PMOS transistor is formed in the n-well. A device isolation film 303 for isolating active regions of NMOS and PMOS transistors may be formed by an STI (Shallow Trench Isolation) process on the substrates 301 and 302.

A silicon oxide film SiO₂ may be deposited as gate insulating film over the entire surfaces of the substrates 301 and 302. Undoped polysilicon may be deposited thereon, and patterned by a photoexposure and etching process using NMOS and PMOS gate masks, thereby forming gate electrodes 304 in an NMOS region and a PMOS region, respectively. Thereafter, the gate insulating film under each of the gate electrodes 304 may be patterned.

An LDD (Light Doped Drain) ion implantation process using n− and p− dopants, respectively, may be performed on the substrates 301 and 302 of the NMOS region and PMOS region, thereby forming n− and p− LDD regions 305 under the sides of the gate electrodes 304. Then, a source/drain ion implantation process using n+ and p+ dopants, respectively, may be performed on the substrates of the NMOS region and PMOS region, thereby forming n+ and p+ source/drain regions 306 under the sides of the gate electrodes 304. A spacer oxide film 307 may be formed as a protective film over the entire surface of the structure in which the n+ and p+ source/drain regions 306 are formed.

Referring to example FIG. 33B, a photoresist film 308 may be formed over the entire surface of the structure in which the spacer oxide film 307 is formed. The photoresist film 308 over the PMOS region may be selectively removed, leaving the photoresist film over only the NMOS region. The spacer oxide film 307 over the PMOS region may be removed using a PEP (Photo Etching Process).

Referring to example FIG. 3C, the photoresist film 308 may be removed by performing, for example, an ashing process, on the structure in which the spacer oxide film 307 of the PMOS region is removed. Silicon germanium SiₓGe₁₋ₓ serving as a lattice stress-causing material is selectively deposited only in the source/drain regions 306 of the PMOS region. Silicon germanium is not deposited in the source/drain regions 306 of the NMOS region due to the protective film function of the spacer oxide film 307, but only in the source/drain regions 106 of the PMOS region. In the drawings, reference numeral 306 is assigned to the source/drain regions over which no silicon germanium is deposited, and reference numeral 309 is assigned to the source/drain regions over which silicon germanium is deposited. The mobility of electrons or holes serving as charge carriers in the MOS transistor is higher in silicon germanium than in silicon, and hence the mobility of the PMOS region having the source/drain regions 309 over which silicon germanium is deposited is improved.

Referring to example FIG. 3D, the spacer oxide film 307 of the NMOS region may be removed by etching. For instance, the spacer oxide film 307 may be removed by wet etching using a BOE (Buffered Oxide Etch) solution or a dilute HF solution.

Referring to example FIG. 3E, a silicon nitride film 210, used as a gapping layer having a tensile stress upon thermal treatment may be formed over the entire surface of the structure in which the spacer oxide film 307 is removed. For example, the silicon nitride film 310 may be deposited using a low pressure chemical vapor deposition (LPCVD) process.

Referring to example FIG. 3F, a photoresist film 311 may be formed over the entire surface of the structure in which the silicon nitride film 310 is formed. The PMOS region may be opened by leaving the photoresist film 311 only over the NMOS region through, for example, a PEP (Photo Etching Process). The silicon nitride film 310 of the PMOS region may be removed by performing wet etching or plasma dry etching using, for example, a phosphoric acid solution, on the structure in which the PMOS region is opened.

The silicon nitride film 310 remains only in the NMOS region. Since the silicon nitride film 310, which has a tensile stress, remains in the NMOS region, a compressive stress develops in response to the tensile stress of the silicon nitride film 310. Since the compressive stress is applied to the gate electrodes 304, a tensile stress as a reactive force against the compressive stress develops in the underside of the gate electrodes 304, i.e., in the substrate 301 of the NMOS region. As the underside of the gate electrodes 304, i.e., the substrate 301 of a channel region, receives a tensile stress, the channel region can obtain the effect of relaxation. When the physical structure of the substrate 301 is relaxed upon receipt of a tensile stress within a limited region, this improves the free movement of electrons or holes. That is, as a tensile stress is applied to the substrate 301 of the NMOS region, the mobility of electrons or holes is improved.

Referring to example FIG. 3G, the photoresist film 311 may be removed by performing, for example, an ashing process, on the structure in which the silicon nitride film 310 of the PMOS region is removed. A spacer oxide film 312 to be utilized as an etch stopping film in a subsequent process may be formed over the entire surface of the structure. A series of processes including forming an interlayer insulating film, a planarization process, a contact electrode formation process, and a wiring formation process are carried out, thereby completing the semiconductor device.

As described above, embodiments can improve the mobility of electrons or holes serving as charge carriers in the MOS transistor by forming a lattice stress-causing material in source/drain regions of a MOS transistor or by forming a gapping layer having a tensile stress caused by a thermal treatment in the MOS transistor. As a result, a driving current of the MOS transistor is improved.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a device isolation film for isolating a first type MOS transistor region and a second type MOS transistor region over a semiconductor substrate;
forming gate electrodes over the first type MOS transistor region and second type MOS transistor region, respectively;
forming lightly doped drain regions over the first type MOS transistor region and second type MOS transistor region, respectively;
forming source/drain regions over the first type MOS transistor region and second type MOS transistor region, respectively;
forming a protective film over the first type MOS transistor region;
selectively forming a lattice stress-causing material over the source/drain regions of the second type MOS transistor region; and
removing the protective film.

2. The method of claim 1, wherein the second type MOS transistor region is a P type MOS transistor region.

3. The method of claim 1, wherein forming a protective film over the first type MOS transistor region and selectively forming a lattice stress-causing material comprises:
forming a protective film over the entire surface of the structure in which the source/drain regions are formed;
forming a photoresist film over the entire surface of the protective film;
exposing the second type MOS transistor region by leaving the photoresist film only in the first type MOS transistor region using a photo etching process;
removing the protective film of the second type MOS transistor region;
removing the photoresist film over the first type MOS transistor region; and
forming the lattice stress-causing material in the source/drain regions of the second type MOS transistor region from which the protective film is removed.

4. The method of claim 1, wherein silicon germanium SiₓGe₁₋ₓ is deposited in the source/drain regions to serve as the lattice stress-causing material.

5. The method of claim 1, the protective film is a spacer oxide film.

6. The method of claim 5, wherein the spacer oxide film is removed by wet etching using one of a buffered oxide etch solution and a dilute HF solution.

7. An apparatus comprising:
a first type MOS transistor region in which source/drain regions, lightly doped drain regions, and gate electrodes are formed over a semiconductor substrate;
a second type MOS transistor region in which source/drain regions having a lattice stress-causing material, lightly doped drain regions, and gate electrodes are formed over a semiconductor substrate; and
a device isolation film for isolating the first type MOS transistor region and the second type MOS transistor region.

8. The apparatus of claim 7, wherein the second type MOS transistor region is a P type MOS transistor region.

9. The apparatus of claim 7, wherein the lattice stress-causing material is formed of silicon germanium SiₓGe₁₋ₓ.

10. A method comprising:
forming a device isolation film for isolating a first type MOS transistor region and a second type MOS transistor region over a semiconductor substrate;
forming gate electrodes over the first type MOS transistor region and second type MOS transistor region, respectively;
forming lightly doped drain regions over the first type MOS transistor region and second type MOS transistor region, respectively;
forming source/drain regions over the first type MOS transistor region and second type MOS transistor region, respectively;
forming a gapping layer having a tensile stress in the first type MOS transistor region.

11. The method of claim 10, wherein the first type MOS transistor region is an N type MOS transistor region.

12. The method of claim 10, wherein forming a gapping layer having a tensile stress comprises:
forming a gapping layer over the entire surface of the structure in which the source/drain regions are formed;
forming a photoresist film over the gapping layer;
exposing the second type MOS transistor region by leaving the photoresist film only in the first type MOS transistor region through a photo etching process; and
leaving the gapping layer only in the first type MOS transistor region by removing the gapping layer over the second type MOS transistor region.

13. The method of claim 10, wherein the gapping layer is a silicon nitride film.

14. The method of claim 13, wherein the silicon nitride film is deposited using a low pressure chemical vapor deposition process.

15. The method of claim 12, wherein, in leaving the gapping layer only in the first type MOS transistor region, the gapping layer is removed over the second type MOS transistor region by one of wet etching and plasma dry etching.

16. An apparatus comprising:
a first type MOS transistor region in which source/drain regions, lightly doped drain regions, and gate electrodes are formed over a semiconductor substrate;
a second type MOS transistor region in which source/drain regions, lightly doped drain regions, and gate electrodes are formed over a semiconductor substrate;
a device isolation film for isolating the first type MOS transistor region and the second type MOS transistor region; and
a gapping layer having a tensile stress formed in the first type MOS transistor region.

17. The apparatus of claim 16, wherein the first type MOS transistor region is an N type MOS transistor region.

18. The apparatus of claim 16, wherein the gapping layer is formed of a silicon nitride film.

19. A method comprising:
forming a device isolation film for isolating a first type MOS transistor region and a second type MOS transistor region over a semiconductor substrate;
forming gate electrodes over the first type MOS transistor region and second type MOS transistor region, respectively;
forming lightly doped drain regions over the first type MOS transistor region and second type MOS transistor region, respectively;
forming source/drain regions over the first type MOS transistor region and second type MOS transistor region, respectively;
forming a protective film over the first type MOS transistor region;
selectively forming a lattice stress-causing material in the source/drain regions of the second type MOS transistor region;
removing the protective film; and
forming a gapping layer having a tensile stress in the first type MOS transistor region.

20. The method of claim 19, wherein the second MOS transistor region is a P type MOS transistor region, and the first type MOS transistor region is an N type MOS transistor region.

21. The method of claim 19, wherein forming a protective film over the first type MOS transistor region and selectively forming a lattice stress-causing material in the source/drain regions of the second type MOS transistor region comprises:
forming a protective film over the entire surface of the structure in which the source/drain regions are formed;
forming a photoresist film over the protective film;
exposing the second type MOS transistor region by leaving the photoresist film only in the first type MOS transistor region through a photo etching process;
removing the protective film over the second type MOS transistor region;
removing the photoresist film over the first type MOS transistor region; and
forming the lattice stress-causing material in the source/drain regions over the second type MOS transistor region from which the protective film is removed.

22. The method of claim 19, wherein silicon germanium SiₓGe₁₋ₓ is deposited in the source/drain regions to serve as the lattice stress-causing material.

23. The method of claim 19, wherein the protective film is a spacer oxide film.

24. The method of claim 23, wherein the spacer oxide film is removed by wet etching using one of a buffered oxide etch solution and a dilute HF solution.

25. The method of claim 19, wherein removing the protective film and forming a gapping layer having a tensile stress in the first type MOS transistor region comprises:
forming a gapping layer over the entire surface of the structure in which the protective film is removed;
forming a photoresist film over the gapping layer;
exposing the second type MOS transistor region by leaving the photoresist film only in the first type MOS transistor region through a photo etching process; and
leaving the gapping layer only in the first type MOS transistor region by removing the gapping layer over the second type MOS transistor region.

26. The method of claim 19, wherein the gapping layer is a silicon nitride film.

27. The method of claim 26, wherein the silicon nitride film is deposited using a low pressure chemical vapor deposition process.

28. The method of claim 25, wherein, in leaving the gapping layer only in the first type MOS transistor region, the gapping layer is removed by one of wet etching and plasma dry etching.

29. An apparatus comprising:
a first type MOS transistor region in which source/drain regions, lightly doped drain regions, and gate electrodes are formed over a semiconductor substrate;
a second type MOS transistor region in which source/drain regions having a lattice stress-causing material, lightly doped drain regions, and gate electrodes are formed over a semiconductor substrate;
a device isolation film for isolating the first type MOS transistor region and the second type MOS transistor region; and
a gapping layer having a tensile stress formed in the first type MOS transistor region.

30. The apparatus of claim 29, wherein the second MOS transistor region is a P type MOS transistor region, and the first MOS transistor region is an N type MOS transistor region.

31. The apparatus of claim 29, wherein the lattice stress-causing material is formed of silicon germanium SiₓGe₁₋ₓ.

32. The apparatus of claim 29, wherein the gapping layer is a silicon nitride film.
